(19) United States
(12) Patent Application Publication
(10) Pub. No.: US 2025/0176267 A1
(43) Pub. Date: May 29, 2025

(54) PIXEL STRUCTURE

(71) Applicant: AUO Corporation, Hsinchu City (TW)

(72) Inventors: Syuan-Ying Lin, Hsinchu City (TW); Cheng-Kuang Wang, Hsinchu City (TW); Min-Hsuan Chiu, Hsinchu City (TW); Wei-Ming Cheng, Hsinchu City (TW)

(73) Assignee: AUO Corporation, Hsinchu City (TW)

(21) Appl. No.: 18/898,643

(22) Filed: Sep. 26, 2024

(30) Foreign Application Priority Data
Nov. 27, 2023 (TW) 112145758

(51) Int. Cl. H01L 27/12; H01L 25/16

(52) U.S. Cl. CPC H10D 86/60; H01L 25/167; H10D 86/441

(57) ABSTRACT

A pixel structure includes a first conductive pattern layer, a voltage line bridge structure, and a second conductive pattern layer. The first conductive pattern layer includes a first light-emitting signal line and a voltage line. The first light-emitting signal line extends in a first direction. The voltage line includes a first voltage line segment and a second voltage line segment located on both sides of the first light-emitting signal line and separated from each other. The first voltage line segment and the second voltage line segment extend in a second direction. The voltage line bridge structure electrically connects the first voltage line segment to the second voltage line segment. The second conductive pattern layer includes a scan line and a first data line. The scan line extends in the first direction. The first data line extends in the second direction and at least partially overlaps the voltage line.

### CROSS-REFERENCE TO RELATED APPLICATION

This application claims the priority benefit of Taiwan application serial no. 112145758, filed on Nov. 27, 2023. The entirety of the above-mentioned patent application is hereby incorporated by reference herein and made a part of specification.

### BACKGROUND

### Technical Field

The disclosure relates to a pixel structure.

### Description of Related Art

In recent years, with the rapid development of display technology, transparent display devices have gradually become the focus. Generally, a transparent display device allows a user to view a displayed image while also allowing the user to see through the device to see the displayed objects or scenes behind the device. In other words, the transparent display device exhibits the conventional display function and also has the unique feature of allowing the user to see through the device to see the background behind. This feature is widely used in various occasions, including large commercial displays, store windows, and merchandise display cabinets, to achieve the goal of displaying advertising images and displaying merchandise at the same time.

### SUMMARY

The disclosure provides a pixel structure having the advantage of high aperture ratio.

At least one embodiment of the disclosure provides a pixel structure including a substrate, a first conductive pattern layer, a voltage line bridge structure, a second conductive pattern layer, and a first subpixel driver circuit. The first conductive pattern layer is located above the substrate and includes a first light-emitting signal line and a voltage line. The first light-emitting signal line extends in a first direction. The voltage line includes a first voltage line segment and a second voltage line segment located on both sides of the first light-emitting signal line and separated from each other. The first voltage line segment and the second voltage line segment extend in a second direction not parallel to the first direction. The voltage line bridge structure electrically connects the first voltage line segment to the second voltage line segment. The second conductive pattern layer includes a scan line and a first data line. The scan line extends in the first direction. The first data line extends in the second direction and at least partially overlaps the voltage line in a normal direction of a top surface of the substrate. The first subpixel driver circuit is electrically connected to the scan line, the first light-emitting signal line, the first data line, and the voltage line.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1F are schematic top views of various pattern layers of a pixel structure according to an embodiment of the disclosure.

FIG. 2 is a schematic cross-sectional view of a pixel structure according to an embodiment of the disclosure.

FIG. 3A to FIG. 3C are schematic partial enlarged views of a first subpixel region, a second subpixel region, and a third subpixel region of FIG. 1C, respectively.

FIG. 4 is a circuit diagram of a subpixel driver circuit according to an embodiment of the disclosure.

### DESCRIPTION OF THE EMBODIMENTS

In the specification, an aperture ratio is defined as a ratio of a region in a pixel structure through which light can pass to an area occupied by the entire pixel structure. Generally, the pixel structure includes an opaque wiring region and a light-permeable aperture region, and the larger the area occupied by the wiring region, the smaller the aperture ratio of the pixel structure. The specification provides a new pixel structure in which the area of the opaque wiring region is effectively reduced, so that the aperture ratio of the pixel structure is increased, and a transparent display device including the pixel structure exhibits the advantage of high transmittance.

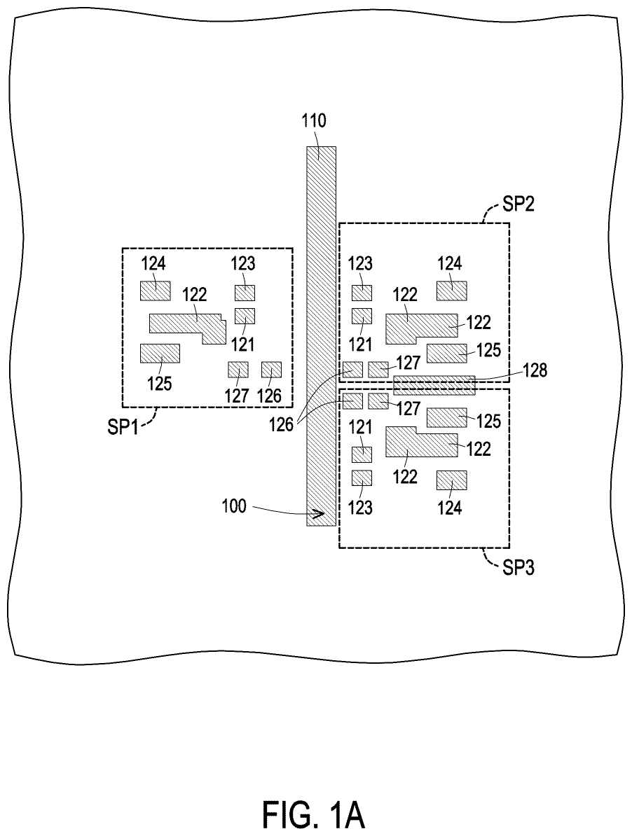

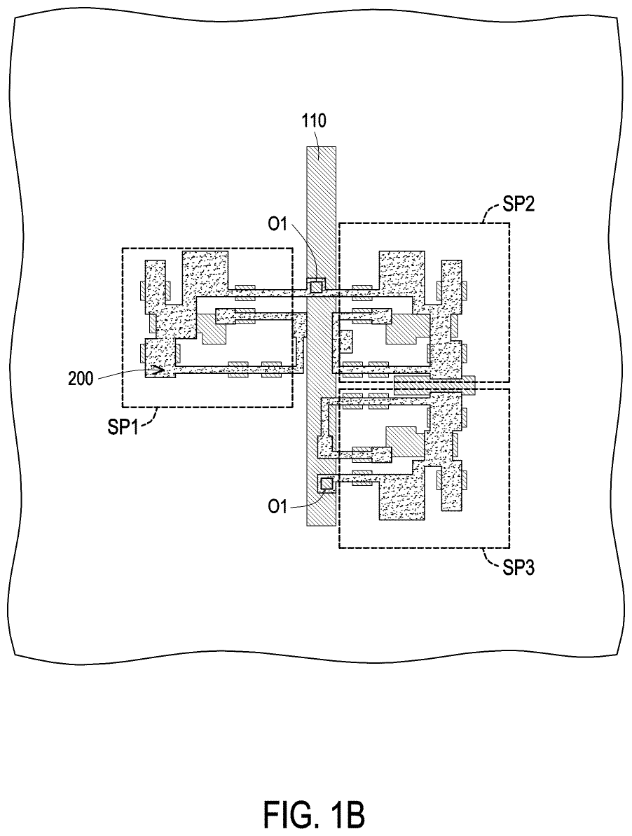

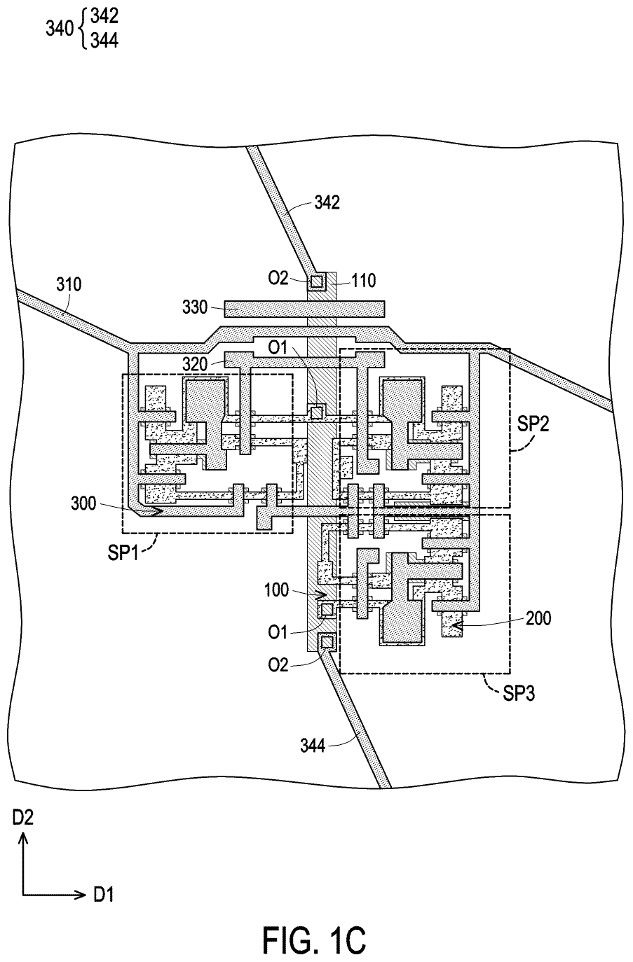

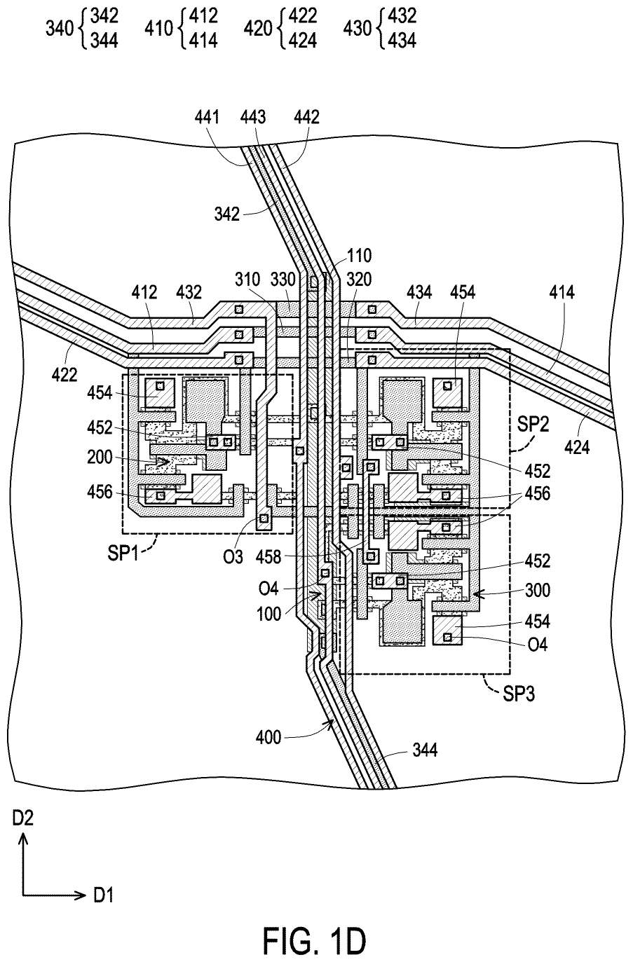

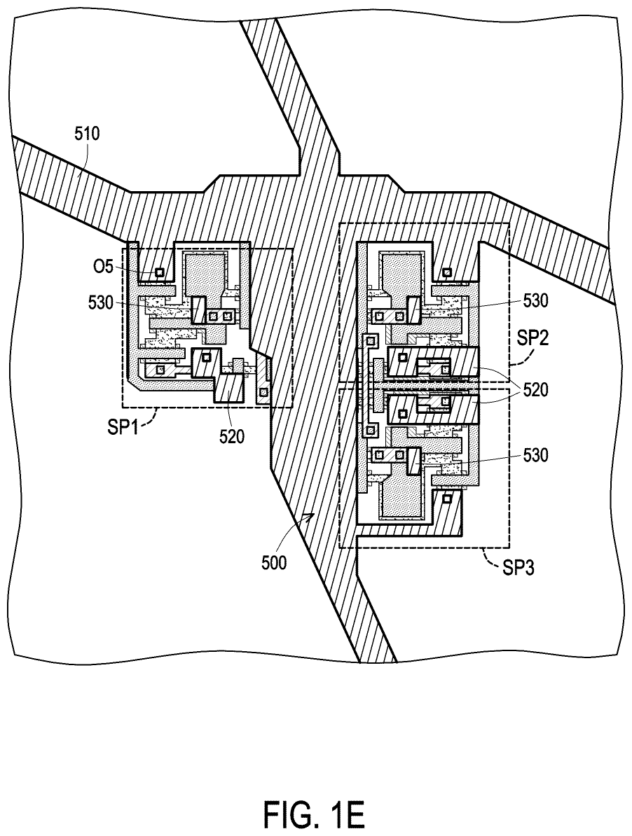

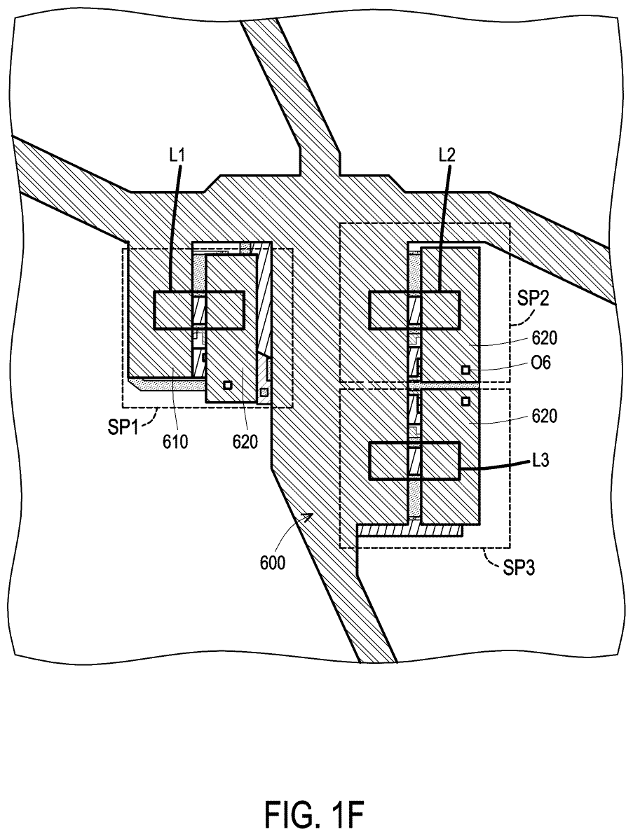

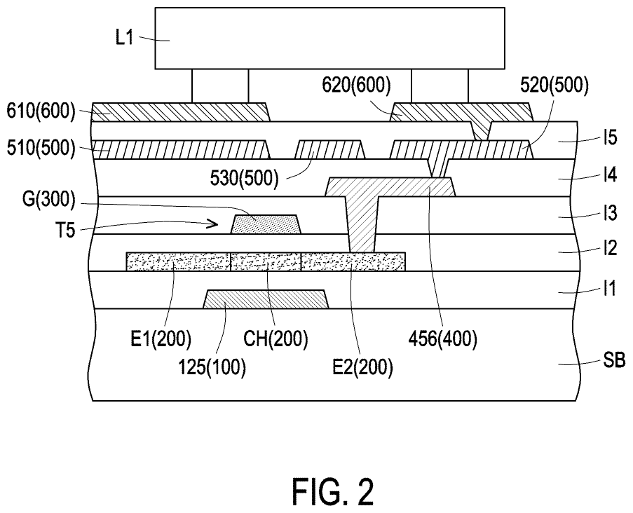

FIG. 1A to FIG. 1F are schematic top views of various pattern layers of a pixel structure according to an embodiment of the disclosure. FIG. 1A to FIG. 1F are used to illustrate a conductor layer and a semiconductor layer in the pixel structure, and a dielectric layer between the film layers is omitted. The arrangement of the dielectric layer between the film layers can refer to FIG. 2. With reference to FIG. 1A, a light-shielding pattern layer 100 is located above a substrate (with reference to a substrate SB in FIG. 2). In some embodiments, before the light-shielding pattern layer 100 is formed, a buffer insulating layer is formed first on the substrate, and then the light-shielding pattern layer 100 is formed on the buffer insulating layer.

In some embodiments, a material of the light-shielding pattern layer 100 includes a metal material (e.g., chromium, gold, silver, copper, tin, lead, uranium, tungsten, molybdenum, neodymium, titanium, tantalum, aluminum, zinc, alloys of the above metals, or stacked layers of the above metals). Nevertheless, the disclosure is not limited thereto. According to other embodiments, the light-shielding pattern layer 100 may also use other conductive materials, such as metal nitride, metal oxide, metal oxynitride, other suitable materials, or a stacked layer of metal and other conductive materials. The light-shielding pattern layer 100 has a single-layer structure or a multi-layer structure.

In some embodiments, the light-shielding pattern layer 100 includes a voltage line bridge structure 110 and a plurality of first light-shielding structures 121 to a plurality of seventh light-shielding structures 127. In some embodiments, the light shielding pattern layer 100 further includes a dummy structure 128. The voltage line bridge structure 110 and the first light-shielding structures 121 to the seventh light-shielding structures 127 are located between a first dielectric layer (with reference to a first dielectric layer I1 in FIG. 2) and the substrate (with reference to the substrate SB in FIG. 2). The dummy structure 128 may further prevent reflected light from emitting from the back of the pixel structure.

In this embodiment, the pixel structure includes a first subpixel region SP1, a second subpixel region SP2, and a third subpixel region SP3. The first subpixel region SP1, the second subpixel region SP2, and the third subpixel region SP3 all have the first light-shielding structures 121 to the seventh light-shielding structures 127. The voltage line bridge structure 110 is located between the first subpixel region SP1 and the second subpixel region SP2 and between the first subpixel region SP1 and the third subpixel region SP3. In some embodiments, the voltage line bridge structure 110 and the first light-shielding structures 121 to the seventh light-shielding structures 127 are separated from each other.

With reference to FIG. 1B, a semiconductor pattern layer 200 is located above the substrate (with reference to the substrate SB in FIG. 2). In some embodiments, the first dielectric layer (with reference to the first dielectric layer I1 in FIG. 2) is formed on the light-shielding pattern layer 100 first, and then the semiconductor pattern layer 200 is formed on the first dielectric layer.

In some embodiments, a material of the semiconductor pattern layer 200 includes amorphous silicon, polycrystalline silicon, microcrystalline silicon, single crystal silicon, an organic semiconductor material, an oxide semiconductor material (e.g., indium zinc oxide, indium gallium zinc oxide, other suitable materials, or a combination of the above materials),other suitable materials, or a combination of the above materials.

In some embodiments, the semiconductor pattern layer 200 includes a doped low resistance region and an undoped high resistance region. In some embodiments, a source/drain of a transistor of a subpixel driver circuit, a first capacitor electrode of a storage capacitor, and the doped region of the semiconductor pattern layer 200 are integrated together. Further, a semiconductor channel region (e.g., a semiconductor channel region CH in FIG. 2) of the transistor of the subpixel driver circuit is integrated with the undoped region of the semiconductor pattern layer 200. In other words, after the semiconductor pattern layer 200 is doped, the source/drain of the transistor of the subpixel driver circuit, the first capacitor electrode of the storage capacitor, and the semiconductor channel region of the transistor of the subpixel driver circuit are formed.

In some embodiments, the semiconductor pattern layer 200 is electrically connected to

the voltage line bridge structure 110 through a plurality of first through holes O1 penetrating through the first dielectric layer (with reference to the first dielectric layer I1 of FIG. 2).

With reference to FIG. 1C, a first conductive pattern layer 300 is located above the substrate (with reference to the substrate SB in FIG. 2). In some embodiments, a second dielectric layer (with reference to a second dielectric layer I2 in FIG. 2) is formed on the semiconductor pattern layer 200 first, and then the first conductive pattern layer 300 is formed on the second dielectric layer. The semiconductor pattern layer 200 is located between the first dielectric layer and the second dielectric layer. In some embodiments, the first conductive pattern layer 300 is electrically connected to the light-shielding pattern layer 100 through a plurality of second through holes O2 penetrating the first dielectric layer and the second dielectric layer (with reference to the first dielectric layer I1 and the second dielectric layer I2 in FIG. 2).

In some embodiments, a material of the first conductive pattern layer 300 includes a metal material (e.g., chromium, gold, silver, copper, tin, lead, uranium, tungsten, molybdenum, neodymium, titanium, tantalum, aluminum, zinc, alloys of the above metals, or stacked layers of the above metals). Nevertheless, the disclosure is not limited thereto. According to other embodiments, the first conductive pattern layer 300 may also use other conductive materials, such as metal nitride, metal oxide, metal oxynitride, other suitable materials, or a stacked layer of metal and other conductive materials. The first conductive pattern layer 300 has a single-layer structure or a multi-layer structure.

The first conductive pattern layer 300 includes a first light-emitting signal line 31, a scan line bridge structure 320, a test line bridge structure 330, and a voltage line 340.

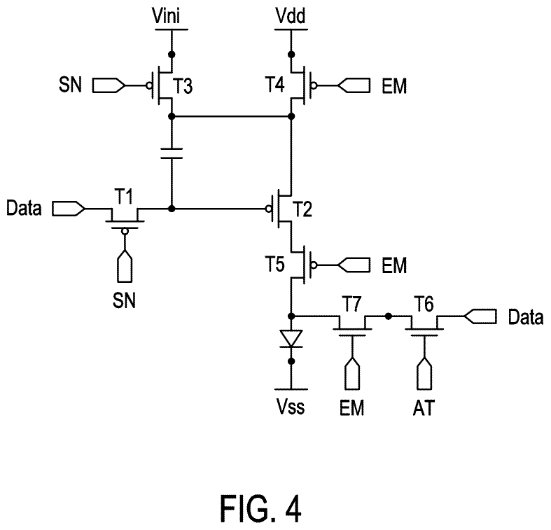

The first light-emitting signal line 310 extends in a first direction D1. In some embodiments, the first light-emitting signal line 310 is used to transmit a light-emitting signal EM (with reference to FIG. 4).

The voltage line 340 includes a first voltage line segment 342 and a second voltage line

segment 344 located on both sides of the first light-emitting signal line 310 and separated from each other. The first voltage line segment 342 and the second voltage line segment 344 extend in a second direction D2 not parallel to the first direction D1. In some embodiments, the first light-emitting signal line 310, the scan line bridge structure 320, and the test line bridge structure 330 are all located between the first voltage line segment 342 and the second voltage line segment 344. The voltage line bridge structure 110 electrically connects the first voltage line segment 342 to the second voltage line segment 344. In some embodiments, the voltage line 340 is used to transmit an activation signal Vini (with reference to FIG. 4).

In some embodiments, a gate of the transistor of the subpixel driver circuit and a second capacitor electrode of the storage capacitor are integrated with the first conductive pattern layer 300. In other words, when the first conductive pattern layer 300 is formed, the gate of the transistor of the subpixel driver circuit and the second capacitor electrode of the storage capacitor are formed.

With reference to FIG. 1D, a second conductive pattern layer 400 is located above the substrate (with reference to the substrate SB in FIG. 2). In some embodiments, a third dielectric layer (with reference to a third dielectric layer 13 in FIG. 2) is formed on the first semiconductor pattern layer 300 first, and then the second conductive pattern layer 400 is formed on the second dielectric layer. The first conductive pattern layer 300 is located between the second dielectric layer and the third dielectric layer. In some embodiments, the second conductive pattern layer 400 is electrically connected to the first conductive pattern layer 300 through a plurality of third through holes O3 penetrating through the third dielectric layer. In some embodiments, the second conductive pattern layer 400 is electrically connected to the first conductive pattern layer 300 through a plurality of fourth through holes O4 penetrating the second dielectric layer and the third dielectric layer (with reference to the second dielectric layer I2 and the third dielectric layer I3 in FIG. 2).

In some embodiments, a material of the second conductive pattern layer 400 includes a metal material (e.g., chromium, gold, silver, copper, tin, lead, uranium, tungsten, molybdenum, neodymium, titanium, tantalum, aluminum, zinc, alloys of the above metals, or stacked layers of the above metals). Nevertheless, the disclosure is not limited thereto. According to other embodiments, the second conductive pattern layer 400 may also use other conductive materials, such as metal nitride, metal oxide, metal oxynitride, other suitable materials, or a stacked layer of metal and other conductive materials. The second conductive pattern layer 400 has a single-layer structure or a multi-layer structure.

The second conductive pattern layer 400 includes a second light-emitting signal line 410, a scan line 420, a test line 430, a first data line 441, a second data line 442, a third data line 443, a plurality of transferring structures 452, 454, and 456, and a connection line 458. In some embodiments, the scan line 420 is used to transmit a scan line signal SN (with reference to FIG. 4), the test line 430 is used to transmit a test signal AT (with reference to FIG. 4), and the first data line 441, the second data line 442, and the third data line 443 are used to transmit a data line signal Data (with reference to FIG. 4).

The first light-emitting signal line 310, the scan line bridge structure 320, and the test line bridge structure 330 cross the first data line 441, the second data line 442, and the third data line 443. The first light-emitting signal line 310, the scan line bridge structure 320, and the test line bridge structure 330 are all located between the voltage line bridge structure 110 (with reference to FIG. 1A) and the first data line 441, the voltage line bridge structure 110 and the second data line 442, and the voltage line bridge structure 110 and the third data line 443.

The second light-emitting signal line 410 includes a first signal line segment 412 and a second signal line segment 414 located on both sides of the first data line 441, the second data line 442, and the third data line 443 and separated from each other. The first signal line segment 412 and the second signal line segment 414 extend in the first direction DI and are electrically connected to the first light-emitting signal line 310. Through the arrangement of the first signal line segment 412 and the second signal line segment 414, loss of the light-emitting signal caused by resistance and capacitance may can be reduced.

The scan line 420 includes a first scan line segment 422 and a second scan line segment 424 located on both sides of the first data line 441, the second data line 442, and the third data line 443 and separated from each other. The first scan line segment 422 and the second scan line segment 424 extend in the first direction D1 and are electrically connected to the scan line bridge structure 320.

The test line 430 includes a first test line segment 432 and a second test line segment 434 located on both sides of the first data line 441, the second data line 442, and the third data line 443 and separated from each other. The first test line segment 432 and the second test line segment 434 extend in the first direction D1 and are electrically connected to the test line bridge structure 330.

The first data line 441, the second data line 442, and the third data line 443 extend in the second direction D2. Further, at least one of the first data line 441, the second data line 442, and the third data line 443 at least partially overlaps the voltage line 340 in the normal direction of the top surface of the substrate (i.e., the direction perpendicular to the paper in FIG. 1D). In some embodiments, the third data line 443 is located between the first data line 441 and the second data line 442. The first voltage line segment 342 partially overlaps a gap between the first data line 441 and the third data line 443 in the normal direction of the top surface of the substrate. Further, the second voltage line segment 344 partially overlaps a gap between the third data line 443 and the second data line 442 in the normal direction of the top surface of the substrate. In this way, interference caused by a signal on the voltage line 340 to signals on the first data line 441, the second data line 442, and the third data line 443 is reduced. Through the arrangement of the voltage line 340 in a conductive pattern layer different from the first data line 441, the second data line 442, and the third data line 443, an aperture ratio of the pixel structure may be effectively increased. In some embodiments, the aperture ratio of the pixel structure ranges from 60% to 85%.

Each of the first subpixel region SP1, the second subpixel region SP2, and the third subpixel region SP3 has the transferring structures 452, 454, and 456. The transferring structures 452, 454, and 456 are separated from one another. The connection line 458 extends from the second subpixel region SP2 to the third subpixel region SP3.

With reference to FIG. 1E, a third conductive pattern layer 500 is located above the substrate (with reference to the substrate SB in FIG. 2). In some embodiments, a fourth dielectric layer (with reference to a fourth dielectric layer 14 in FIG. 2) is formed on the second semiconductor pattern layer 400 first, and then the third conductive pattern layer 500 is formed on the fourth dielectric layer. The second conductive pattern layer 400 is located between the third dielectric layer and the fourth dielectric layer. In some embodiments, the third conductive pattern layer 500 is electrically connected to the second conductive pattern layer 400 through a plurality of fifth through holes O5 penetrating through the fourth dielectric layer.

In some embodiments, a material of the third conductive pattern layer 500 includes a metal material (e.g., chromium, gold, silver, copper, tin, lead, uranium, tungsten, molybdenum, neodymium, titanium, tantalum, aluminum, zinc, alloys of the above metals, or stacked layers of the above metals). Nevertheless, the disclosure is not limited thereto. According to other embodiments, the third conductive pattern layer 500 may also use other conductive materials, such as metal nitride, metal oxide, metal oxynitride, other suitable materials, or a stacked layer of metal and other conductive materials. The third conductive pattern layer 500 has a single-layer structure or a multi-layer structure.

The third conductive pattern layer 500 includes a first power line 510, a plurality of connection structures 520, and a plurality of light-shielding structures 530.

With reference to FIG. 1D and FIG. 1E, the first power line 510 at least partially overlaps the first light-emitting signal line 310, the voltage line 340, the second light-emitting signal line 410, the scan line 420, the test line 430, the first data line 441, the second data line 442, and the third data line 443 in the normal direction of the top surface of the substrate. In some embodiments, the first power line 510 is used to transmit a first operating voltage signal Vdd (with reference to FIG. 4).

Each of the first subpixel region SP1, the second subpixel region SP2, and the third subpixel region SP3 has one connection structure 520.

With reference to FIG. 1F, a fourth conductive pattern layer 600 is located above the substrate (with reference to the substrate SB in FIG. 2). In some embodiments, a fifth dielectric layer (with reference to a fifth dielectric layer 15 in FIG. 2) is formed on the third semiconductor pattern layer 500 first, and then the fourth conductive pattern layer 600 is formed on the fifth dielectric layer. The third conductive pattern layer 500 is located between the fourth dielectric layer and the fifth dielectric layer. In some embodiments, the fourth conductive pattern layer 600 is electrically connected to the third conductive pattern layer 500 through a plurality of sixth through holes O6 penetrating through the fifth dielectric layer.

In some embodiments, a material of the fourth conductive pattern layer 600 includes a metal material (e.g., chromium, gold, silver, copper, tin, lead, uranium, tungsten, molybdenum, neodymium, titanium, tantalum, aluminum, zinc, alloys of the above metals, or stacked layers of the above metals). Nevertheless, the disclosure is not limited thereto. According to other embodiments, the fourth conductive pattern layer 600 may also use other conductive materials, such as metal nitride, metal oxide, metal oxynitride, other suitable materials, or a stacked layer of metal and other conductive materials. The fourth conductive pattern layer 600 has a single-layer structure or a multi-layer structure.

With reference to FIG. 1D, FIG. 1E, and FIG. IF, the fourth conductive pattern layer 600 includes a second power line 610 and a plurality of pads 620. The second power line 610 at least partially overlaps the first light-emitting signal line 310, the voltage line 340, the second light-emitting signal line 410, the scan line 420, the test line 430, the first data line 441, the second data line 442, the third data line 443, and the first power line 510 in the normal direction of the top surface of the substrate. In some embodiments, the second power line 610 is used to transmit a second operating voltage signal Vss (with reference to FIG. 4).

Each of the first subpixel region SP1, the second subpixel region SP2, and the third subpixel region SP3 has one pad 620.

The first light-emitting diode L1, the second light-emitting diode L2, and the third light-emitting diode L3 are respectively disposed in the first subpixel region SP1, the second subpixel region SP2, and the third subpixel region SP3 and are electrically connected to the pads 620. In this embodiment, a first electrode of each of the first light-emitting diode L1, the second light-emitting diode L2, and the third light-emitting diode L3 is electrically connected to the second power line 610. Further, a second electrode of each of the first light-emitting diode L1, the second light-emitting diode L2, and the third light-emitting diode L3 is electrically connected to the corresponding pad 620.

In some embodiments, the light-shielding structures (with reference to FIG. 1E) overlap gaps between the pads 620 and the second power line 610 and may be used to shield light emitted by the first light-emitting diode L1, the second light-emitting diode L2, and the third light-emitting diode L3.

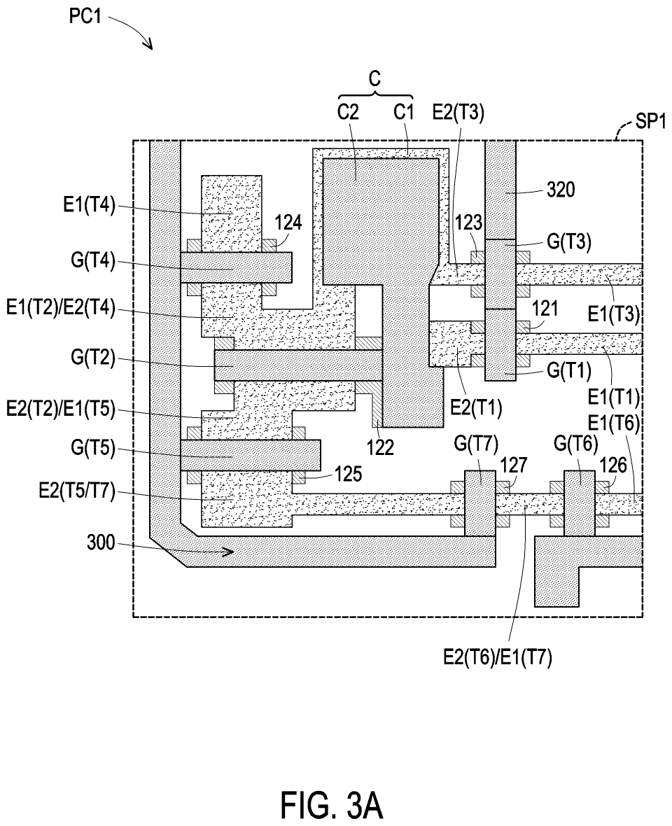

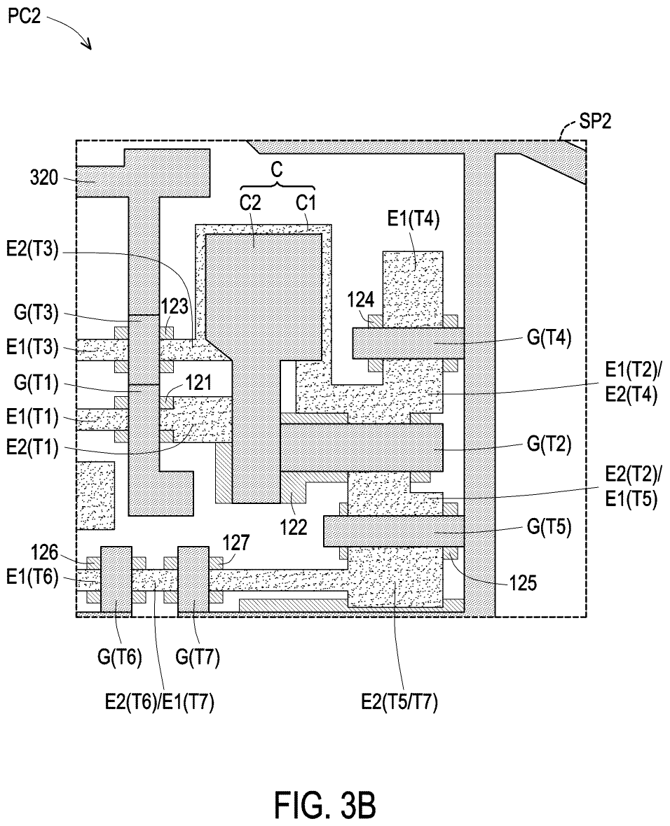

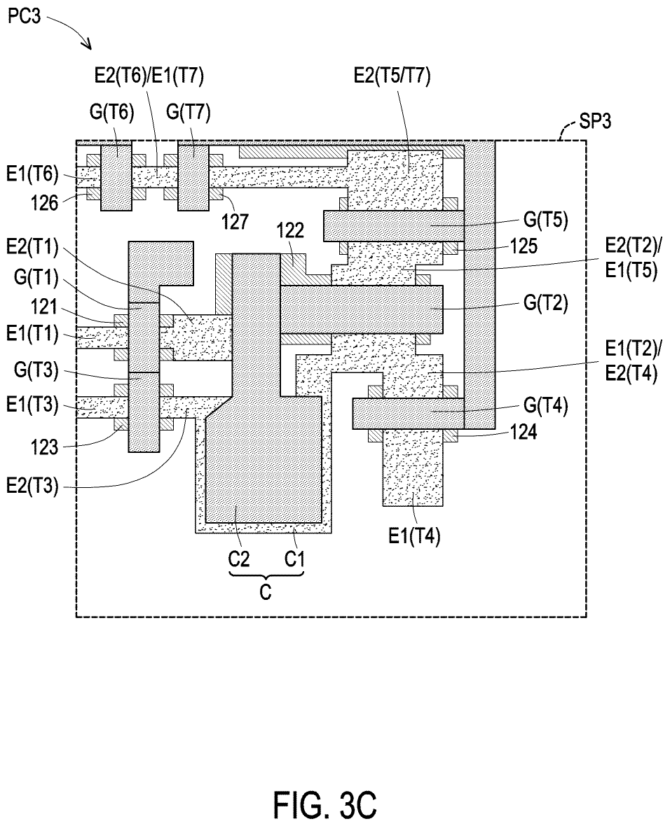

In some embodiments, a first subpixel driver circuit PC1, a second subpixel driver circuit PC2, and a third subpixel driver circuit PC3 are respectively configured to control the first light-emitting diode L1, the second light-emitting diode L2, and the third light-emitting diode L3. The first subpixel driver circuit PC1, the second subpixel driver circuit PC2, and the third subpixel driver circuit PC3 are electrically connected to the first light-emitting signal line 310, the voltage line 340, the scan line 420, and the test line 430. Further, the first subpixel driver circuit PC1, the second subpixel driver circuit PC2, and the third subpixel driver circuit PC3 are electrically connected to the first data line 441, the second data line 442, and the third data line 443, respectively. Next, the first subpixel driver circuit PC1, the second subpixel driver circuit PC2, and the third subpixel driver circuit PC3 are described using FIG. 3A to FIG. 3C and FIG. 4.

FIG. 3A to FIG. 3C are schematic partial enlarged views of the first subpixel region SP1, the second subpixel region SP2, and the third subpixel region SP3 of FIG. 1C, respectively. FIG. 4 is a circuit diagram of a subpixel driver circuit according to an embodiment of the disclosure. In this embodiment, the first subpixel driver circuit SP1, the second subpixel driver circuit SP2, and the third subpixel driver circuit SP3 have the same circuit diagram, as shown in FIG. 4.

With reference to FIG. 1D and FIG. 3A to FIG. 3C, the first subpixel driver circuit PC1 is located on first sides (e.g., the left side in FIG. 1D) of the first data line 441, the second data line 442, and the third data line 443. Further, the second subpixel driver circuit PC2 and the third subpixel driver circuit PC3 are located on second sides (e.g., the right side in FIG. 1D) opposite to the first sides of the first data line 441, the second data line 442, and the third data line 443. The first subpixel driver circuit PC1 is located in the first subpixel region SP1, the second subpixel driver circuit PC2 is located in the second subpixel region SP2, and the third subpixel driver circuit PC3 is located in the third subpixel region SP3.

With reference to FIG. 1D, FIG. 3A to FIG. 3C, and FIG. 4, each of the first subpixel driver circuit PC1, the second subpixel driver circuit PC2, and the third subpixel driver circuit

PC3 includes a first transistor TI to a seventh transistor T7. In this embodiment, a semiconductor channel region (e.g., the semiconductor channel region CH in FIG. 2) of each of the first transistor T1 to the seventh transistor T7 is located between a first source/drain (e.g., a first source/drain E1 in FIG. 2) and a second source/drain (e.g., a second source/drain E2 in FIG. 2). Further, the semiconductor channel regions of the first transistor T1 to the seventh transistor T7 are respectively located between corresponding gates G and the first light-shielding structure 121 to the seventh light-shielding structure 127. The first light-shielding structure 121 to the seventh light-shielding structure 127 are used to shield the semiconductor channel regions of the first transistor T1 to the seventh transistor T7 respectively, so as to prevent light from irradiating the semiconductor channel regions and causing leakage current.

The gate G of the first transistor T1 is electrically connected to the scan line 420. In this embodiment, the gate G of the first transistor T1 of each of the first subpixel driver circuit PC1 and the second subpixel driver circuit PC2 is electrically connected to the scan line 420 through the scan line bridge structure 320. The gate G of the first transistor T1 of the third subpixel driver circuit PC3 is electrically connected to the scan line bridge structure 320 through the connection line 458 and is further electrically connected to the scan line 420.

The first drain/source E1 of the first transistor T1 of the first subpixel driver circuit PC1, the first drain/source E1 of the first transistor T1 of the second subpixel driver circuit PC2, and the first drain/source E1 of the first transistor T1 of the third subpixel driver circuit PC3 are electrically connected to the first data line 441, the second data line 442, and the third data line 443, respectively.

The gate G of the second transistor T2 is electrically connected to the second drain/source E2 of the first transistor T1. For instance, the transferring structure 452 is electrically connected to the second drain/source E2 of the first transistor T1 through the fourth through holes O4 and is electrically connected to the gate G of the second transistor T2 through the third through holes O3.

The gate G of the third transistor T3 is electrically connected to the scan line 420. In this embodiment, the first transistor T1 and the gate G of the third transistor T3 of the first subpixel driver circuit PC1 and the first transistor T1 and the gate G of the third transistor T3 of the second subpixel driver circuit PC2 and the scan line bridge structure 320 are integrally connected. Further, the first transistor T1 and the gate G of the third transistor T3 of the third subpixel driver circuit PC3 are integrally connected.

The first source/drain E1 of the third transistor T3 is electrically connected to the voltage line 340 through the voltage line bridge structure 110.

A first capacitor electrode C1 of a storage capacitor C is electrically connected to the second drain/source E2 of the third transistor T3, and a second capacitor electrode C2 of the storage capacitor C is electrically connected to the second drain/source E2 of the first transistor T1 and the gate G of the second transistor T2. In this embodiment, the second capacitor electrode C2 and the gate G of the second transistor T2 are integrally connected.

The gate G of the fourth transistor T4 is electrically connected to the first light-emitting signal line 310. The first source/drain E1 of the fourth transistor T4 is electrically connected to the transferring structure 454 (with reference to FIG. 1D) and is further connected to the first power line 510 (with reference to FIG. 1E).

The second source/drain E2 of the fourth transistor T4 is electrically connected to the first source/drain E1 of the second transistor T2, the first capacitor electrode C1 of the storage capacitor C, and the second drain/source E2 of the third transistor T3.

The gate G of the fifth transistor T5 is electrically connected to the first light-emitting signal line 310. The first source/drain E1 of the fifth transistor T5 is electrically connected to the second source/drain E2 of the second transistor T2. The second source/drain E2 of the fifth transistor T5 is electrically connected to the transferring structure 456 (with reference to FIG. 1D and FIG. 2) and is further connected to the connection structures 520 (with reference to FIG. 1E and FIG. 2) and the pads 620 (with reference to FIG. 1F and FIG. 2). In other words, in the pixel structure, the three connection structures 520 are electrically connected to the fifth transistor T5 of the first subpixel driver circuit PC1, the fifth transistor T5 of the second subpixel driver circuit PC2, and the fifth transistor T5 of the third subpixel driver circuit PC3, respectively. Further, the three pads 620 are electrically connected to the fifth transistor T5 of the first subpixel driver circuit PC1, the fifth transistor T5 of the second subpixel driver circuit PC2, and the fifth transistor T5 of the third subpixel driver circuit PC3, respectively.

The gate G of the sixth transistor T6 is electrically connected to the test line 430. In this embodiment, the first subpixel driver circuit PC1, the second subpixel driver circuit PC2, and the gate G of the sixth transistor T6 of the third subpixel driver circuit PC3 are integrally connected.

The first drain/source E1 of the sixth transistor T6 of the first subpixel driver circuit PC1, the first drain/source E1 of the sixth transistor T6 of the second subpixel driver circuit PC2, and the first drain/source E1 of the sixth transistor T1 of the third subpixel driver circuit PC3 are electrically connected to the first data line 441, the second data line 442, and the third data line 443, respectively (with reference to FIG. 1D).

The gate G of the seventh transistor T7 is electrically connected to the first light-emitting signal line 310. In this embodiment, the gate G of the fourth transistor T4, the gate G of the fifth transistor T5, and the gate G of the seventh transistor T7 are integrally connected.

The first source/drain E1 of the seventh transistor T7 is electrically connected to the second source/drain E2 of the sixth transistor T6. The second source/drain E2 of the seventh transistor T7 is electrically connected to the transferring structure 456 (with reference to FIG. 1D) and is further connected to the connection structures 520 (with reference to FIG. 1E) and the pads 620 (with reference to FIG. 1F).

In view of the foregoing, in the disclosure, the voltage line is disposed in the first conductive pattern layer, and the first data line at least partially overlaps the voltage line. In this way, the aperture ratio of the pixel structure may be effectively improved, so that the transparent display device including the pixel structure has the advantage of high transmittance.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel structure, comprising:
a substrate;
a first conductive pattern layer located above the substrate and comprising:
a first light-emitting signal line extending in a first direction; and
a voltage line comprising a first voltage line segment and a second voltage line segment located on both sides of the first light-emitting signal line and separated from each other, wherein the first voltage line segment and the second voltage line segment extend in a second direction not parallel to the first direction;
a voltage line bridge structure electrically connecting the first voltage line segment to the second voltage line segment;
a second conductive pattern layer, comprising:
a scan line extending in the first direction; and
a first data line extending in the second direction and at least partially overlapping the voltage line in a normal direction of a top surface of the substrate; and
a first subpixel driver circuit electrically connected to the scan line, the first light-emitting signal line, the first data line, and the voltage line.

2. The pixel structure according to claim 1, wherein the second conductive pattern layer further comprises:
a second light-emitting signal line comprising a first signal line segment and a second signal line segment located on both sides of the first data line and separated from each other, wherein the first signal line segment and the second signal line segment extend in the first direction and are electrically connected to the first light-emitting signal line, and the first conductive pattern layer further comprises:
a scan line bridge structure, wherein the scan line comprises a first scan line segment and a second scan line segment located on both sides of the first data line and separated from each other, and the first scan line segment and the second scan line segment extend in the first direction and are electrically connected to the scan line bridge structure, wherein the scan line bridge structure and the first light-emitting signal line cross the first data line.

3. The pixel structure according to claim 1, further comprising:
a first dielectric layer, wherein the voltage line bridge structure is located between the first dielectric layer and the substrate;
a semiconductor pattern layer located on the first dielectric layer;
a second dielectric layer located on the semiconductor pattern layer located between the first dielectric layer and the second dielectric layer, wherein the first conductive pattern layer is located on the second dielectric layer;
a third dielectric layer located on the first conductive pattern layer, wherein the second conductive pattern layer is located on the third dielectric layer;
a fourth dielectric layer located on the second conductive pattern layer;
a third conductive pattern layer located on the fourth dielectric layer and comprising:
a first power line at least partially overlapping the scan line, the voltage line, and the first light-emitting signal line in the normal direction of the top surface of the substrate; and
a connection structure electrically connected to the first subpixel driver circuit;
a fifth dielectric layer located on the third conductive pattern layer located between the fifth dielectric layer and the fourth dielectric layer; and
a fourth conductive pattern layer located on the fifth dielectric layer and comprising:
a second power line at least partially overlapping the scan line, the voltage line, and the first light-emitting signal line in the normal direction of the top surface of the substrate; and
a pad electrically connected to the connection structure; and
a first light-emitting diode electrically connected to the pad and the second power line, wherein the first subpixel driver circuit is configured to control the first light-emitting diode.

4. The pixel structure according to claim 3, wherein the first subpixel driver circuit comprises:
a first transistor, wherein a gate of the first transistor is electrically connected to the scan line, and a first drain/source of the first transistor is electrically connected to the first data line;
a second transistor, wherein a gate of the second transistor is electrically connected to a second drain/source of the first transistor;
a third transistor, wherein a gate of the third transistor is electrically connected to the scan line, and a first source/drain of the third transistor is electrically connected to the voltage line;
a storage capacitor, wherein a first capacitor electrode of the storage capacitor is electrically connected to a second drain/source of the third transistor, and a second capacitor electrode of the storage capacitor is electrically connected to a second drain/source of the first transistor; and
a fourth transistor, wherein a gate of the fourth transistor is electrically connected to the first light-emitting signal line, a first source/drain of the fourth transistor is electrically connected to the first power line, and a second source/drain of the fourth transistor is electrically connected to a first source/drain of the second transistor; and
a fifth transistor, wherein a gate of the fifth transistor is electrically connected to the first light-emitting signal line, a first source/drain of the fifth transistor is electrically connected to a second source/drain of the second transistor, and a second source/drain of the fifth transistor is electrically connected to the pad.

5. The pixel structure according to claim 4, wherein the second conductive pattern layer further comprises:
a test line, and the first subpixel driver circuit further comprises:
a sixth transistor, wherein a gate of the sixth transistor is electrically connected to the test line, and a first source/drain of the sixth transistor is electrically connected to the first data line; and
a seventh transistor, wherein a gate of the seventh transistor is electrically connected to the first light-emitting signal line, a first source/drain of the seventh transistor is electrically connected to a second source/drain of the sixth transistor, and a second source/drain of the seventh transistor is electrically connected to the pad.

6. The pixel structure according to claim 1, wherein the second conductive pattern layer further comprises:
a second data line and a third data line extending in the second direction, and the pixel structure further comprises:
a second subpixel driver circuit electrically connected to the scan line, the first light-emitting signal line, the second data line, and the voltage line;
a third subpixel driver circuit electrically connected to the scan line, the first light-emitting signal line, the third data line, and the voltage line;
a first light-emitting diode electrically connected to the first subpixel driver circuit;
a second light-emitting diode electrically connected to the second subpixel driver circuit; and
a third light-emitting diode electrically connected to the third subpixel driver circuit.

7. The pixel structure according to claim 6, wherein the first subpixel driver circuit is located on first sides of the first data line, the second data line, and the third data line, and the second subpixel driver circuit and the third subpixel driver circuit are located on second sides opposite to the first sides of the first data line, the second data line, and the third data line, wherein the pixel structure comprises a first subpixel region, a second subpixel region, and a third subpixel region, wherein the first subpixel driver circuit and the first light-emitting diode are located in the first subpixel region, the second subpixel driver circuit and the second light-emitting diode are located in the second subpixel region, and the third subpixel driver circuit and the third light-emitting diode are located in the third subpixel region.

8. The pixel structure according to claim 6, wherein the third data line is located between the first data line and the second data line, wherein the first voltage line segment partially overlaps a gap between the first data line and the third data line in the normal direction of the top surface of the substrate, and the second voltage line segment partially overlaps a gap between the third data line and the second data line in the normal direction of the top surface of the substrate.

9. The pixel structure according to claim 6, further comprising:
a first dielectric layer, wherein the voltage line bridge structure is located between the first dielectric layer and the substrate;
a semiconductor pattern layer located on the first dielectric layer;
a second dielectric layer located on the semiconductor pattern layer located between the first dielectric layer and the second dielectric layer, wherein the first conductive pattern layer is located on the second dielectric layer;
a third dielectric layer located on the first conductive pattern layer, wherein the second conductive pattern layer is located on the third dielectric layer;
a fourth dielectric layer located on the second conductive pattern layer;
a third conductive pattern layer located on the fourth dielectric layer and comprising:
a first power line at least partially overlapping the scan line, the voltage line, and the first light-emitting signal line in the normal direction of the top surface of the substrate; and
a plurality of connection structures electrically connected to the first subpixel driver circuit, the second subpixel driver circuit, and the third subpixel driver circuit;
a fifth dielectric layer located on the third conductive pattern layer located between the fifth dielectric layer and the fourth dielectric layer; and
a fourth conductive pattern layer located on the fifth dielectric layer and comprising:
a second power line at least partially overlapping the scan line, the voltage line, and the first light-emitting signal line in the normal direction of the top surface of the substrate; and
a plurality of pads electrically connected to the connection structures, wherein the first light-emitting diode, the second light-emitting diode, and the third light-emitting diode are electrically connected to the pads.

10. The pixel structure according to claim 1. wherein the first light-emitting signal line is located between the voltage line bridge structure and the first data line.
